(19) United States
(12) Patent Application Publication
(10) Pub. No.: US 2007/0290224 A1
(43) Pub. Date: Dec. 20, 2007

(54) Method of manufacturing nitride semiconductor light-emitting element and nitride semiconductor light-emitting element

(75) Inventor: Atsushi Ogawa, Mihara-shi (JP)

Correspondence Address: MORRISON & FOERSTER LLP, 1650 TYSONS BOULEVARD, SUITE 400, MCLEAN, VA, 22102, US

(73) Assignee: SHARP KABUSHIKI KAISHA, Osaka-shi (JP)

(21) Appl. No.: 11/808,220

(22) Filed: Jun. 7, 2007

(30) Foreign Application Priority Data
Jun. 15, 2006 (JP) 2006-166000
Mar. 30, 2007 (JP) 2007-093321

(51) Int. Cl. H01L 33/00

(52) U.S. Cl. 257/103

(57) ABSTRACT

There are provided a method of manufacturing a nitride semiconductor light-emitting element in which a nitride semiconductor layer of a first conductivity type, an active layer, and a nitride semiconductor layer of a second conductivity type are stacked in this order, including the steps of forming unevenness at a surface of the nitride semiconductor layer of the first conductivity type, forming unevenness at a surface of the nitride semiconductor layer of the second conductivity type, and forming a first electrode on a side of the nitride semiconductor layer of the first conductivity type and a second electrode on a side of the nitride semiconductor layer of the second conductivity type such that the first and second electrodes are positioned to face each other with the active layer interposed therebetween, and the nitride semiconductor light-emitting element.

This nonprovisional application is based on Japanese Patent Applications Nos. 2006-166000 and 2007-093321 filed with the Japan Patent Office on Jun. 15, 2006 and Mar. 30, 2007 respectively, the entire contents of which are hereby incorporated by reference.

### BACKGROUND OF THE INVENTION

1. Field of the Invention

The present invention relates to a method of manufacturing a nitride semiconductor light-emitting element, and the nitride semiconductor light-emitting element, and particularly relates to a method of manufacturing a nitride semiconductor light-emitting element, and the nitride semiconductor light-emitting element, both of which can suppress degradation of an active layer and improve light extraction efficiency.

2. Description of the Background Art

FIG. 15 is a schematic cross-sectional view showing a conventional configuration of a light-emitting diode (LED), which is an example of a nitride semiconductor light-emitting element. The conventional LED has a configuration in which a p-type Si supporting substrate 102, a metal layer 103 made of a stacked body including a Ti layer and an Au layer, an Au—Sn metal junction layer 104, a metal barrier layer 105, a metal reflective layer 106, a p-type GaN-side ohmic layer 107, a p-type GaN layer 111, a p-type AlGaN evaporation-preventing layer 112, an InGaN active layer 113, an n-type GaN layer 114, a transparent conductive film 120, and an n electrode 121 are stacked in this order on a p electrode 101.

In the conventional LED, p-type GaN layer 111, p-type AlGaN evaporation-preventing layer 112, InGaN active layer 113, and n-type GaN layer 114 form a layer structure of the nitride semiconductor light-emitting element.

In the LED configured as such, it is said to be possible to suppress total reflection of light generated at InGaN active layer 113 and improve light extraction efficiency by forming unevenness at a surface of n-type GaN layer 114 (e.g. see Patent Document 1 (Japanese Patent Laying-Open No. 2003-031841)).

### SUMMARY OF THE INVENTION

As in the LED shown in FIG. 15; however, if unevenness is formed only on one side of the layer structure of the nitride semiconductor light-emitting element, the active layer tends to be distorted during formation of the unevenness. If the active layer is distorted, it is damaged during a wafer grinding step and a wafer polishing step before dicing of the wafer into a plurality of elements, and during a wafer dicing step by means of a laser, a dicer, or Reactive Ion Etching (RIE), and this inevitably results in property degradation of the nitride semiconductor light-emitting element.

Accordingly, an object of the present invention is to provide a method of manufacturing a nitride semiconductor light-emitting element, and the nitride semiconductor light-emitting element, both of which can suppress degradation of an active layer and improve light extraction efficiency.

The present invention is a method of manufacturing a nitride semiconductor light-emitting element in which a nitride semiconductor layer of a first conductivity type, an active layer, and a nitride semiconductor layer of a second conductivity type are stacked in this order, including the steps of: forming unevenness at a surface of the nitride semiconductor layer of the first conductivity type; forming unevenness at a surface of the nitride semiconductor layer of the second conductivity type; and forming a first electrode on a side of the nitride semiconductor layer of the first conductivity type and a second electrode on a side of the nitride semiconductor layer of the second conductivity type such that the first and second electrodes are positioned to face each other with the active layer interposed therebetween.

In the method of manufacturing the nitride semiconductor light-emitting element according to the present invention, a conductive layer can be provided at least one of between the nitride semiconductor layer of the first conductivity type and the first electrode, and between the nitride semiconductor layer of the second conductivity type and the second electrode.

Furthermore, in the method of manufacturing the nitride semiconductor light-emitting element according to the present invention, the conductive layer may contain a conductive substance containing at least one selected from the group consisting of a nitride semiconductor, silicon carbide (hereinafter also referred to as “SiC”), silicon (hereinafter also referred to as “Si”), zinc oxide (hereinafter also referred to as “ZnO”), gallium arsenide (hereinafter also referred to as “GaAs”), and gallium phosphide (hereinafter also referred to as “GaP”).

Furthermore, in the method of manufacturing the nitride semiconductor light-emitting element according to the present invention, unevenness may be formed at a surface of the conductive layer.

Furthermore, in the method of manufacturing the nitride semiconductor light-emitting element according to the present invention, the unevenness at the surface of the nitride semiconductor layer of the first conductivity type or the unevenness at the surface of the nitride semiconductor layer of the second conductivity type preferably engage with the unevenness at the surface of the conductive layer.

Furthermore, in the method of manufacturing the nitride semiconductor light-emitting element according to the present invention, after the nitride semiconductor layer of the first conductivity type, the active layer, and the nitride semiconductor layer of the second conductivity type are stacked in this order on a surface of a substrate, the surface having unevenness, the substrate can be removed.

Furthermore, in the method of manufacturing the nitride semiconductor light-emitting element, the unevenness at the surface of the substrate can be formed by stacking on the surface of the substrate a mask layer made of at least one of a silicon oxide layer and a silicon nitride layer and subsequently removing a portion of the mask layer, exposing the surface of the substrate through the removed portion of the mask layer, and subsequently removing an exposed portion of the surface of the substrate.

Furthermore, in the method of manufacturing the nitride semiconductor light-emitting element according to the present invention, the nitride semiconductor layer of the first conductivity type, the active layer, and the nitride semiconductor layer of the second conductivity type may be stacked after a buffer layer is formed on the surface of the substrate, the surface having the unevenness. A temperature at which the buffer layer is formed is preferably equal to or higher than a temperature at which the nitride semiconductor layer of the first conductivity type is stacked.

Furthermore, in the method of manufacturing the nitride semiconductor light-emitting element according to the present invention, the first conductivity type may be an n type, while the second conductivity type may be a p type.

Furthermore, the present invention is a nitride semiconductor light-emitting element in which a nitride semiconductor layer of a first conductivity type, an active layer, and a nitride semiconductor layer of a second conductivity type are stacked in this order, in which a first electrode on a side of the nitride semiconductor layer of the first conductivity type and a second electrode on a side of the nitride semiconductor layer of the second conductivity type are formed such that the first and second electrodes are positioned to face each other with the active layer interposed therebetween, and unevenness is formed at both of a surface of the nitride semiconductor layer of the first conductivity type and a surface of the nitride semiconductor layer of the second conductivity type.

According to the present invention, it is possible to provide a method of manufacturing a nitride semiconductor light-emitting element, and the nitride semiconductor light-emitting element, both of which can suppress degradation of an active layer and improve light extraction efficiency.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross-sectional view of an example of a nitride semiconductor light-emitting element according to the present invention.

FIG. 2 is a schematic cross-sectional view showing a part of a step of manufacturing the nitride semiconductor light-emitting element shown in FIG. 1.

FIG. 3 is a schematic cross-sectional view showing a part of the step of manufacturing the nitride semiconductor light-emitting element shown in FIG. 1.

FIG. 4 is a schematic cross-sectional view showing a part of the step of manufacturing the nitride semiconductor light-emitting element shown in FIG. 1.

FIG. 5 is a schematic cross-sectional view showing a part of the step of manufacturing the nitride semiconductor light-emitting element shown in FIG. 1.

FIG. 6 is a schematic cross-sectional view showing a part of the step of manufacturing the nitride semiconductor light-emitting element shown in FIG. 1.

FIG. 7 is a schematic cross-sectional view showing a part of the step of manufacturing the nitride semiconductor light-emitting element shown in FIG. 1.

FIG. 8 is a schematic cross-sectional view showing a part of the step of manufacturing the nitride semiconductor light-emitting element shown in FIG. 1.

FIG. 9 is a schematic cross-sectional view showing a part of the step of manufacturing the nitride semiconductor light-emitting element shown in FIG. 1.

FIG. 10 is a schematic cross-sectional view showing a part of the step of manufacturing the nitride semiconductor light-emitting element shown in FIG. 1.

FIG. 11 is a schematic cross-sectional view showing a part of the step of manufacturing the nitride semiconductor light-emitting element shown in FIG. 1.

FIG. 12 is a schematic cross-sectional view showing a part of the step of manufacturing the nitride semiconductor light-emitting element shown in FIG. 1.

FIG. 13 is a schematic cross-sectional view showing a part of the step of manufacturing the nitride semiconductor light-emitting element shown in FIG. 1.

FIG. 14 is a schematic side view of an example of a light-emitting device fabricated with the use of the nitride semiconductor light-emitting element shown in FIG. 1.

FIG. 15 is a schematic cross-sectional view of a conventional nitride semiconductor light-emitting element.

### DESCRIPTION OF THE PREFERRED EMBODIMENTS

Embodiments of the present invention will hereinafter be described. Assume that the same reference characters in the drawings of the present invention represent the same or corresponding portions.

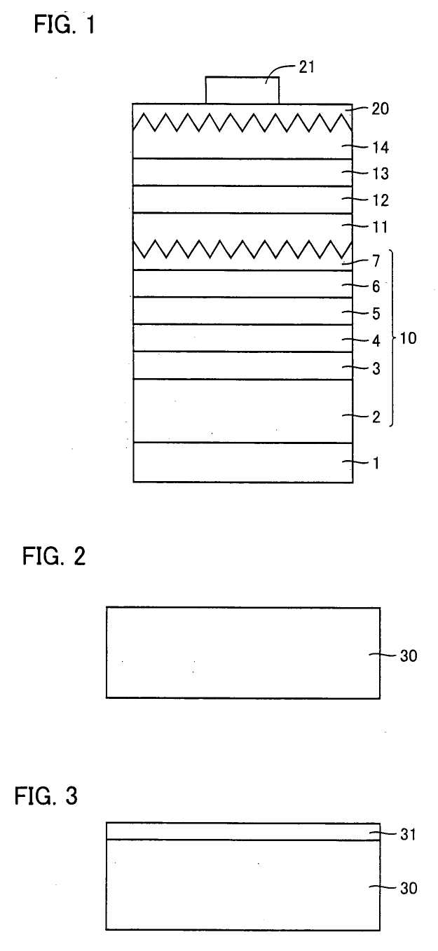

FIG. 1 is a schematic cross-sectional view of an example of a nitride semiconductor light-emitting element according to the present invention. In the nitride semiconductor light-emitting element, a supporting substrate 2 made of p-type silicon, a supporting substrate-side metal layer 3 made of a stacked body including a Ti layer and an Au layer, a metal junction layer 4 made of an alloy of Au and Sn, a metal barrier layer 5 made of a stacked body including an alloy layer of Ni and Ti and an Au layer, a metal reflective layer 6 made of Ag, an ohmic metal layer 7 made of Pd, a nitride semiconductor layer 11 of a second conductivity type made of p-type GaN, a nitride semiconductor evaporation-preventing layer 12 made of p-type Al_{0.15}Ga_{0.85}N, an active layer 13 made of InGaN, a nitride semiconductor layer 14 of a first conductivity type made of n-type GaN, a first conductive layer 20 made of a transparent conductive film, and a first electrode 21 made of a stacked body in which a Ti layer, an Al layer, a Ti layer, and an Au layer are stacked in this order, are formed in this order on a second electrode 1 made of a stacked body including a Ti layer and an Au layer. A stacked body including conductive supporting substrate 2, supporting substrate-side metal layer 3, metal junction layer 4, metal barrier layer 5, metal reflective layer 6, and ohmic metal layer 7 forms a second conductive layer 10.

In the nitride semiconductor light-emitting element, first electrode 21 on a side of nitride semiconductor layer 14 of the first conductivity type and second electrode 1 on a side of nitride semiconductor layer 11 of the second conductivity type are formed such that the first and second electrodes are positioned to face each other with active layer 13 interposed therebetween. Furthermore, unevenness is formed at both of a surface of nitride semiconductor layer 14 of the first conductivity type and a surface of nitride semiconductor layer 11 of the second conductivity type.

As such, unevenness is formed at both of the surface of nitride semiconductor layer 14 of the first conductivity type and the surface of nitride semiconductor layer 11 of the second conductivity type in the nitride semiconductor light-emitting element according to the present invention, and hence total reflection of light generated at active layer 13 is suppressed. Additionally, distortion of the active layer caused during a process of manufacturing the same is cancelled out to a certain degree by the unevenness on both sides. It is therefore possible to further reduce distortion of the active layer, when compared with the conventional case where unevenness is formed only on one side. Accordingly, it is possible to improve light extraction efficiency and suppress degradation of the active layer in the nitride semiconductor light-emitting element according to the present invention.

For example, the nitride semiconductor light-emitting element according to the present invention can be manufactured as follows. As shown in a schematic cross-sectional view in FIG. 2, a substrate 30 made of a sapphire substrate is initially prepared. Next, as shown in a schematic cross-sectional view in FIG. 3, a mask layer 31 made of at least one of a silicon oxide layer and a silicon nitride layer is stacked on an entire surface of substrate 30. A thickness of mask layer 31 can be set to fall within a range of, for example, 100 nm-500 nm.

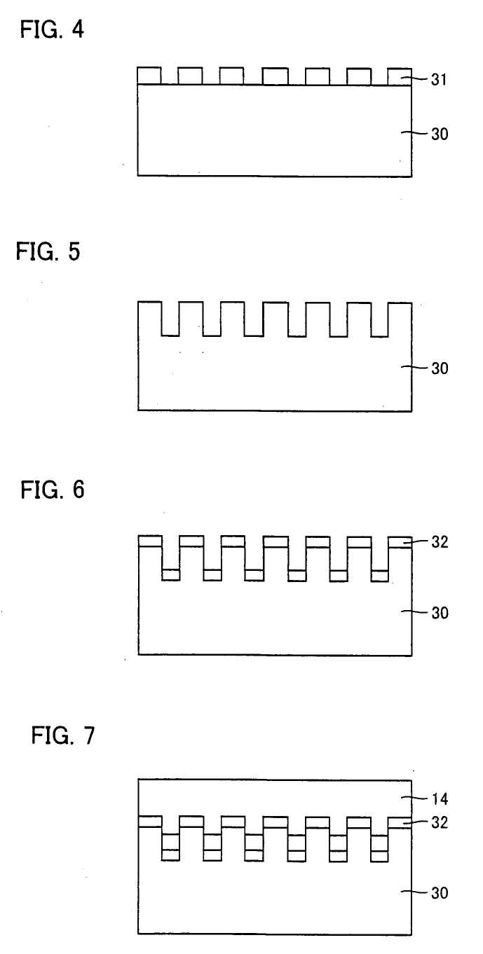

Next, as shown in a schematic cross-sectional view in FIG. 4, mask layer 31 is removed in a stripe-like manner to expose a surface of substrate 30. Note that shape and size of a portion of mask layer 31 to be removed can be set as appropriate, respectively, in the present invention.

Subsequently, an exposed portion of the surface of substrate 30 is etched by RIE, for example, and mask layer 31 is then removed, to form unevenness at the surface of substrate 30 as shown in a schematic cross-sectional view in FIG. 5.

Substrate 30 having unevenness formed at its surface is placed in a vapor deposition device such as a Metal Organic Chemical Vapor Deposition (MOCVD) device. Subsequently, substrate 30 is heated in the vapor deposition device to a temperature of 1100° C., for example, to clean the surface of substrate 30, and as shown in a schematic cross-sectional view in FIG. 6, a buffer layer 32 made of Al_{0.02}Ga_{0.98}N is then formed at the cleaned surface of substrate 30 by vapor deposition.

Subsequently, as shown in a schematic cross-sectional view in FIG. 7, nitride semiconductor layer 14 of the first conductivity type is formed on buffer layer 32 by vapor deposition. At this time, nitride semiconductor layer 14 of the first conductivity type is formed such that it does not fill a groove composing a concave portion of the unevenness at the surface of substrate 30.

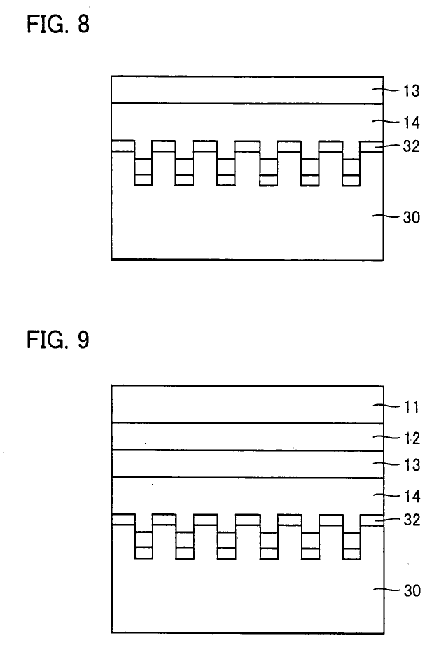

As shown in a schematic cross-sectional view in FIG. 8, active layer 13 is formed on a surface of nitride semiconductor layer 14 of the first conductivity type by vapor deposition. Note that a thickness of active layer 13 can be set, for example, to approximately 0.5 nm-3 nm.

Afterwards, as shown in a schematic cross-sectional view in FIG. 9, nitride semiconductor evaporation-preventing layer 12 and nitride semiconductor layer 11 of the second conductivity type are formed in this order on active layer 13 by vapor deposition. Note that there is no particular need to form nitride semiconductor evaporation-preventing layer 12 in the present invention.

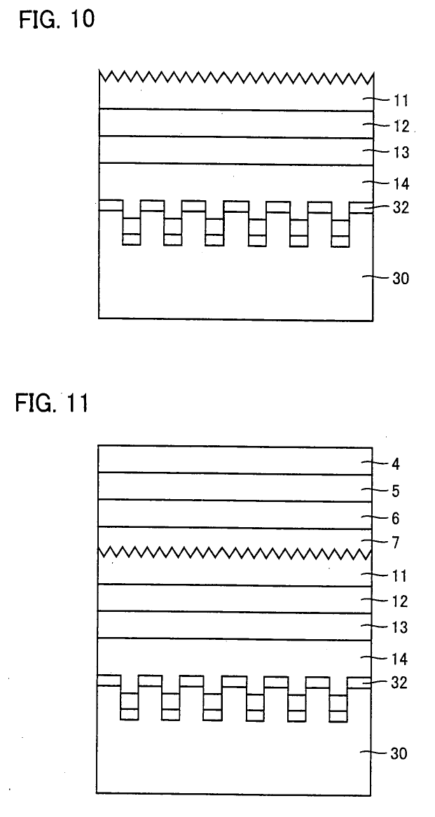

Next, as shown in a schematic cross-sectional view in FIG. 10, unevenness is formed at a surface of nitride semiconductor layer 11 of the second conductivity type. As a method of forming the unevenness at the surface of nitride semiconductor layer 11 of the second conductivity type, it is possible to use, for example, a method of forming a mask layer having a prescribed pattern at the surface of nitride semiconductor layer 11 of the second conductivity type by using a photolithography technique, and then removing a portion of the surface of nitride semiconductor layer 11 of the second conductivity type by RIE or the like, a method by wet etching, and others.

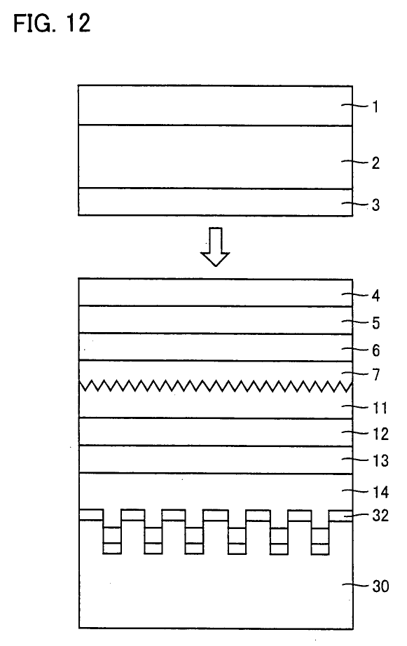

Subsequently, as shown in a schematic cross-sectional view in FIG. 11, ohmic metal layer 7, metal reflective layer 6, metal barrier layer 5, and metal junction layer 4 are formed in this order on the surface of nitride semiconductor layer 11 of the second conductivity, the surface having the unevenness, by an evaporation method or the like. Note that an Electron Beam (EB) evaporation method, a resistance heating evaporation method, or the like may be used as the evaporation method. As shown in a schematic cross-sectional view in FIG. 12, supporting substrate-side metal layer 3 of a stacked body, which is made by forming second electrode 1 on one surface of supporting substrate 2 by an EB evaporation method or the like and forming supporting substrate-side metal layer 3 on the other surface of supporting substrate 2 by an EB evaporation method or the like, is made to face metal barrier layer 5 with metal junction layer 4 interposed therebetween.

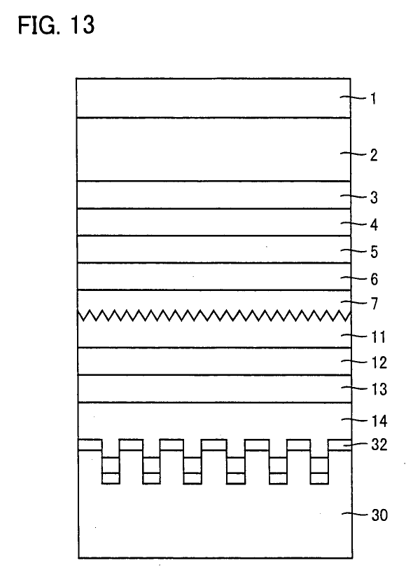

As shown in a schematic cross-sectional view in FIG. 13, the above-described stacked body, which is made of second electrode 1, supporting substrate 2, and supporting substrate-side metal layer 3, is bonded by an eutectic bonding method. Afterwards, yttrium aluminum garnet third harmonic generation (YAG-THG) laser light (wavelength: 355 nm) is applied from a rear side of substrate 30, so that buffer layer 32 kept in contact with substrate 30 and a portion of nitride semiconductor layer 14 of the first conductivity type are thermally decomposed to remove substrate 30. At this time, unevenness is formed at a surface of nitride semiconductor layer 14 of the first conductivity type.

Afterwards, a surface of the unevenness of nitride semiconductor layer 14 of the first conductivity type is cleaned, and then first conductive layer 20 and first electrode 21 are formed in this order. Through dicing with application of laser light, the use of a dicer, an RIE, or the like, there is obtained the nitride semiconductor light-emitting element shown in FIG. 1 according to the present invention.

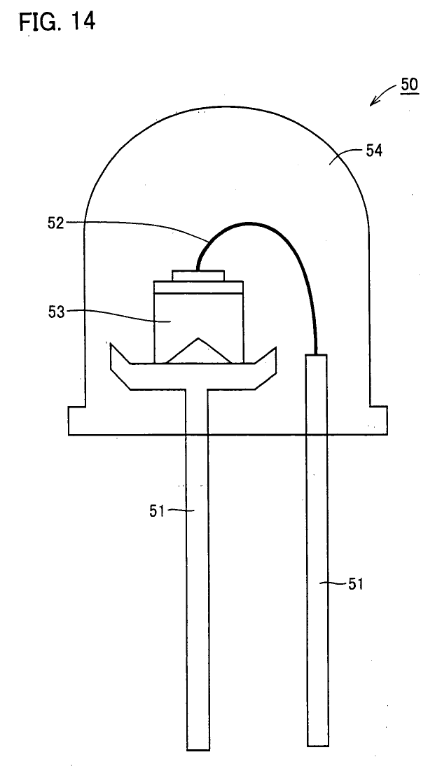

The nitride semiconductor light-emitting element according to the present invention, obtained as such, can be used, for example, for a light-emitting device 50 shown in a schematic side view shown in FIG. 14. Light-emitting device 50 herein has a configuration in which a nitride semiconductor light-emitting element 53 according to the present invention is electrically connected between a pair of lead frames 51 via a wire 52 and sealed with a shell-like transparent resin 54.

In the description above, n-type GaN is used as nitride semiconductor layer 14 of the first conductivity type, InGaN is used as active layer 13, and p-type GaN is used as nitride semiconductor layer 11 of the second conductivity type. In the present invention, however, materials of the nitride semiconductor layer of the first conductivity type, the active layer, and the nitride semiconductor layer of the second conductivity type are not limited thereto, and it is possible to use a nitride semiconductor made of at least one type of nitride selected from the group consisting of aluminum (Al), indium (In), and gallium (Ga). Furthermore, by doping a nitride semiconductor that composes nitride semiconductor layer 14 of the first conductivity type with donor impurities and doping a nitride semiconductor that composes nitride semiconductor layer 11 of the second conductivity type with acceptor impurities, nitride semiconductor layer 14 of the first conductivity type and nitride semiconductor layer 11 of the second conductivity type can be formed into an n-type nitride semiconductor and a p-type nitride semiconductor, respectively. In the description above, the first conductivity type is an n type, while the second conductivity type is a p type. In the present invention, however, the only requirement is that the first conductivity type is different from the second conductivity type, and hence the first conductivity type may be a p type, while the second conductivity type may be an n type. Si, germanium (Ge), selenium (Se), or the like may be used, for example, as the donor impurities, while magnesium (Mg), zinc (Zn), carbon (C), beryllium (Be), calcium (Ca), barium (Ba), or the like may be used, for example, as the acceptor impurities.

Similarly, materials of the first electrode and the second electrode in the present invention are of course not limited to the above-described ones.

In the present invention, the active layer may be composed of a single bulk active layer. However, the active layer may form a quantum well structure such as a single quantum well (SQW) structure, a double quantum well (DQW) structure, or a multiple quantum well (MQW) structure. Furthermore, in the quantum well structure, a barrier layer for separating the quantum well(s) may also be used additionally, as needed. If the active layer is made of an InGaN layer, in particular, the entire element achieves a structure easiest to manufacture, and hence it is possible to improve properties of the nitride semiconductor light-emitting element according to the present invention. Furthermore, the InGaN layer has strong tendency to crystallize and obtains favorable crystallinity, particularly when grown on an S plane having a structure less likely to allow detachment of nitrogen atoms therefrom, so that the InGaN layer makes it possible to improve luminous efficiency of the nitride semiconductor light-emitting element according to the present invention.

In the description above, nitride semiconductor layer 14 of the first conductivity type, active layer 13, and nitride semiconductor layer 11 of the second conductivity type are successively stacked on the surface of substrate 30. However, each of nitride semiconductor layer 14 of the first conductivity type, active layer 13, and nitride semiconductor layer 11 of the second conductivity type may be parallel to, or tilted with respect to, the surface of substrate 30. Furthermore, for substrate 30, it is also use a SiC substrate, a GaN substrate, an Si substrate, a ZnS substrate, a ZnO substrate, an AlN substrate, an LiMgO substrate, a GaAs substrate, an MgAl₂O₄ substrate, an InAlGaN substrate, or the like, other than the sapphire substrate. Note that there is no need in the present invention to form unevenness at the surface of substrate 30.

In the description above, Al_{0.02}Ga_{0.98}N is used as a material of buffer layer 32. In the present invention, however, a material of the buffer layer is not particularly limited thereto, and gallium nitride, aluminum nitride, or the like may also be used. In the present invention, the number of buffer layer is not limited to one, and two or more buffer layers may be used.

In the present invention, a temperature at which the buffer layer is formed is preferably equal to or higher than a temperature at which the nitride semiconductor layer of the first conductivity type is stacked. In this case, crystallinity of nitride semiconductor layer 14 of the first conductivity type made of n-type GaN is improved, and consequently, crystallinity of active layer 13 is also improved, so that luminous efficiency tends to improve. Note that it is possible to check whether or not the temperature at which the buffer layer is formed is equal to or higher than the temperature at which the nitride semiconductor layer of the first conductivity type is stacked, by comparing a substrate temperature when the buffer layer is formed with a substrate temperature when the nitride semiconductor layer of the first conductivity type is stacked.

In the present invention, a configuration of each of first conductive layer 20 and second conductive layer 10 is not limited to the above-described one, and may contain a conductive substance containing at least one selected from the group consisting of, for example, a nitride semiconductor, silicon carbide, silicon, zinc oxide, gallium arsenide, and gallium phosphide. In the present invention, first conductive layer 20, second conductive layer 10, or both of them may not particularly be formed.

In the present invention, a method of forming the unevenness at the surface of the nitride semiconductor layer of the first conductivity type and a method of forming the unevenness at the surface of the nitride semiconductor layer of the second conductivity type are of course not limited to the above-described ones.

In the present invention, the unevenness at the surface of nitride semiconductor layer 14 of the first conductivity type and the unevenness at the surface of the first conductive layer 20 may not engage with each other. However, they preferably engage with each other, because, if so, sticking strength between nitride semiconductor layer 14 of the first conductivity type and first conductive layer 20 is increased and light extraction efficiency can be improved as well, owing to reduction in total reflection.

### EXAMPLE 1

Initially, a sapphire substrate was prepared as a substrate, and a mask layer made of a silicon nitride layer was formed on a surface (C+ plane) of the sapphire substrate. Next, a photolithography technique and a hydrofluoric acid etchant were used to remove a portion of the mask layer, so as to leave the mask layer in the form of stripes, each extending in approximately parallel with <11-20> of the sapphire substrate and having a width of approximately 3 μm, and expose the surface of the sapphire substrate in the form of stripes, each having a width of 2 μm.

Subsequently, an exposed portion of the surface of the sapphire substrate was etched by RIE to a depth of approximately 0.5 μm, to form unevenness at the surface of the sapphire substrate. The sapphire substrate having the unevenness formed at its surface was then placed in an MOCVD device, and the sapphire substrate was heated to a temperature of 1100° C. to clean the surface thereof. Subsequently, trimethylaluminum (TMA), trimethylgallium (TMG), NH₃, and a carrier gas were introduced into the MOCVD device, so that a buffer layer made of Al_{0.02}Ga_{0.98}N was grown from the vapor, while the temperature of the sapphire substrate was kept at Afterwards, monosilane (SiH₄), TMG, NH₃, and a carrier gas were introduced into the MOCVD device with the temperature of the sapphire substrate kept at 1000° C., so that a nitride semiconductor layer of a first conductivity type made of n-type GaN was grown from the vapor on the buffer layer. At that time, the nitride semiconductor layer of the first conductivity type was formed such that it did not fill a groove that composes a concave portion of the unevenness at the surface of the sapphire substrate.

Subsequently, the temperature of the sapphire substrate was lowered, and trimethylindium (TMI), TMG, NH₃, and a carrier gas were introduced into the MOCVD device, so that an active layer made of InGaN was grown from the vapor on the nitride semiconductor layer of the first conductivity type. The active layer was formed such that light generated therefrom had a wavelength of 450 nm as a main peak.

Afterwards, the temperature of the sapphire substrate was raised again, and biscyclopentadienylmagnesium (Cp₂Mg), TMA, TMG, NH₃, and a carrier gas were introduced into the MOCVD device, so that a nitride semiconductor evaporation-preventing layer made of p-type Al_{0.15}Ga_{0.85}N was grown from the vapor on the active layer. Subsequently, Cp₂Mg, TMG, NH₃, and a carrier gas were introduced into the MOCVD device, so that a nitride semiconductor layer of a second conductivity type made of p-type GaN was grown from the vapor on the nitride semiconductor evaporation-preventing layer.

Next, unevenness was formed at a surface of the nitride semiconductor layer of the second conductivity type by wet etching. The unevenness at the surface of the nitride semiconductor layer of the second conductivity type was made in the form of quadrangular pyramids each having a square base with a side of 0.1 μm, and having a height of approximately 0.1 μm.

Subsequently, an ohmic metal layer made of a Pd layer having a thickness of 3.5 nm, a metal reflective layer made of an Ag layer having a thickness of 200 nm, a metal barrier layer made of an Au layer having a thickness of 500 nm and an alloy layer of Ni and Ti having a thickness of 100 nm, and a metal junction layer made of an alloy layer of Au and Sn and having a thickness of 3 μm were formed in this order on a surface of the unevenness of the nitride semiconductor layer of the second conductivity type by an evaporation method. Note that the metal junction layer contained 20 mass % of Sn.

Furthermore, on opposite surfaces of a supporting substrate made of p-type silicon, there were successively formed a Ti layer having a thickness of 50 nm and an Au layer having a thickness of 1 μm, respectively, by an EB evaporation method. Accordingly, there was obtained a stacked body in which a second electrode was formed on one surface of the supporting substrate, while a supporting substrate-side metal layer was formed on the other surface thereof.

The stacked body described above was made to face the metal barrier layer with the metal junction layer interposed therebetween, and was bonded thereto by an eutectic bonding method. The eutectic bonding method was implemented under the conditions of a temperature of 310° C. and a pressure of 300 N/cm².

Next, YAG-THG laser light having a wavelength of 355 nm was applied from a rear side of the sapphire substrate, so that the buffer layer and a portion of the nitride semiconductor layer of the first conductivity type were thermally decomposed to remove the sapphire substrate. At that time, unevenness was formed at a surface of the nitride semiconductor layer of the first conductivity type.

Afterwards, a surface of the unevenness at the nitride semiconductor layer of the first conductivity type was cleaned by RIE, wet etching, or the like, and then an Indium Tin Oxide (ITO) identified as a transparent conductive film having a thickness of 150 nm was formed, as a first conductive layer, at approximately the entire surface of the unevenness at the nitride semiconductor layer of the first conductivity type. A Ti layer, an Al layer, a Ti layer, and an Au layer were formed by evaporation in this order on the first conductive layer to form a first electrode.

A surface of the wafer obtained as described above was ground and polished by means of a grinding/polishing machine commercially available, and the wafer was diced with a dicer so that there was obtained a nitride semiconductor light-emitting element in Example 1 having a configuration shown in FIG. 1.

Internal quantum efficiency of the nitride semiconductor light-emitting element in Example 1 obtained as such was determined. The result was that a mean value of internal quantum efficiency of 10 nitride semiconductor light-emitting elements in Example 1 was 62%.

Note that the internal quantum efficiency was calculated by applying He—Cd laser light to the nitride semiconductor light-emitting element in Example 1 under the conditions of a temperature of 10K and a temperature of 300 K to measure intensities of Photo Luminescence (PL) light generated from the nitride semiconductor light-emitting element in Example 1, and using the following expression.

Internal Quantum Efficiency (%)=100×(Intensity of PL Light at Temperature of 300 K)/(Intensity of PL Light at Temperature of 10 K)

Furthermore, the nitride semiconductor light-emitting element in Example 1 was electrically connected between a pair of lead frames by mounting the second electrode of the nitride semiconductor light-emitting element in Example 1 on a stem with the use of an Ag paste, and connecting a wire to the first electrode thereof. The nitride semiconductor light-emitting element in Example 1 was then sealed with a shell-type transparent resin, so that a light-emitting device having a configuration shown in FIG. 14 was fabricated.

With the use of the light-emitting device in Example 1 obtained as such, light extraction efficiency was calculated from an optical output obtained by measuring total luminous flux at a current of 20 mA, and internal quantum efficiency. The result was that a mean value of light extraction efficiency of 10 nitride semiconductor light-emitting elements in Example 1 was 59%.

In the case where the nitride semiconductor layer of the first conductivity type, the active layer, and the nitride semiconductor layer of the second conductivity type were stacked without unevenness being formed at the surface (C+ plane) of the sapphire substrate, and unevenness was formed, after the removal of the sapphire substrate, at the surface of the nitride semiconductor layer of the first conductivity type by means of laser light, RIE, or wet etching, it was possible even to obtain internal quantum efficiency and light extraction efficiency that were as favorable as those in the nitride semiconductor light-emitting element in Example 1 described above.

Alternatively, assume the following case. A low-temperature buffer layer was formed at the surface (C+ plane) of the sapphire substrate, then the temperature was raised to form at 1000° C. a GaN layer doped with silicon, and subsequently a silicon oxide layer or a silicon nitride layer was formed as a mask layer to have a thickness falling within the range of 100 nm-500 nm, and a circular opening having a diameter of approximately 10 μm was formed in the mask layer by means of photolithography and a hydrofluoric acid etchant. After the nitride semiconductor layer of the first conductivity type, the active layer, and the nitride semiconductor layer of the second conductivity type were stacked, the sapphire substrate was removed to fabricate a nitride semiconductor light-emitting element. Note that it was possible even in that case to obtain internal quantum efficiency and light extraction efficiency that were as favorable as those in the nitride semiconductor light-emitting element in Example 1 described above.

Furthermore, a nitride semiconductor light-emitting element was fabricated in a manner similar to that of Example 1, except that the mask layer was left in the form of stripes each approximately parallel with <1-100> of the sapphire substrate and each having a width of approximately 3 μm, that the surface of the sapphire substrate was exposed in the form of stripes each having a width of 2 μm, and that an exposed portion of the surface of the sapphire substrate was etched by RIE to a depth of approximately 1.0 μm. Even in the case of such fabrication, it was also possible to obtain a nitride semiconductor LED element having internal quantum efficiency and light extraction efficiency that were as favorable as those in the nitride semiconductor light-emitting element in Example 1. Here, <1-100> is a direction along which the groove is more likely to be filled with the nitride semiconductor when compared with <11-20>. Accordingly, the depth of the concave portion at the surface of the sapphire substrate was made to have a large depth of approximately 1.0 μm, so as to prevent the groove from being filled completely. Even if the groove is completely filled, effects of the present invention are exhibited in any of the case where a groove in the <1-100> direction is formed and the case where a groove in the <11-20> direction is formed. However, it is preferable that the groove is not completely filled, because the sapphire substrate can more easily be detached from the nitride semiconductor.

Alternatively, even in the case where a conductive substance made of Ge, SiC, Si, ZnO, GaAs, or GaP was used as a material of the supporting substrate, effects of improving internal quantum efficiency and light extraction efficiency were also observed as in the nitride semiconductor light-emitting element in Example 1 described above.

### Comparative Example 1

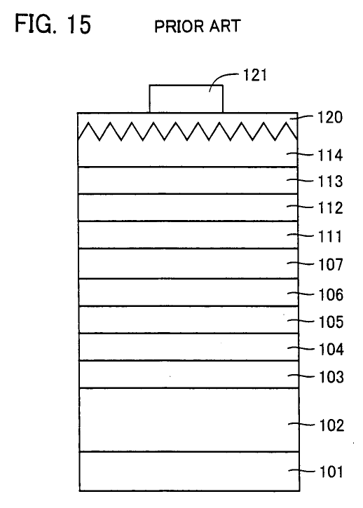

A nitride semiconductor light-emitting element was fabricated in a manner similar to that of Example 1, except that unevenness was not formed at the surface of the nitride semiconductor layer of the second conductivity type made of p-type GaN. There was thus obtained a nitride semiconductor light-emitting element in Comparative Example 1 having a configuration shown in FIG. 15, in which unevenness was formed only at the surface of the nitride semiconductor layer of the first conductivity type made of n-type GaN.

Internal quantum efficiency of the nitride semiconductor light-emitting element in Comparative Example 1 was determined in a manner similar to that of Example 1. A mean value of internal quantum efficiency of 10 nitride semiconductor light-emitting elements in Comparative Example 1 was 45%.

As is clear from this result, internal quantum efficiency of the nitride semiconductor light-emitting element in Example 1 was improved when compared with that of the nitride semiconductor light-emitting element in Comparative Example 1. This seems to be attributable to the fact that, in the nitride semiconductor light-emitting element in Example 1, the unevenness was formed at both of the surface of the nitride semiconductor layer of the first conductivity type and the surface of the nitride semiconductor layer of the second conductivity type, and hence the unevenness on both sides cancelled out the distortion of the active layer caused during a step of heating, grinding, polishing, or the like to a certain degree, so that a defect such as dislocation was less likely to be generated and degradation of the active layer could be suppressed.

Furthermore, a light-emitting device was fabricated in a manner similar to that of Example 1, except that the nitride semiconductor light-emitting element in Comparative Example 1 was used instead of the nitride semiconductor light-emitting element in Example 1. Light extraction efficiency of the light-emitting device in Comparative Example 1 fabricated as such was calculated in a manner similar to that of Example 1. The result was that a mean value of light extraction efficiency of 10 nitride semiconductor light-emitting elements in Comparative Example 1 was 41%.

As is clear from this result, light extraction efficiency of the nitride semiconductor light-emitting element in Example 1 was improved when compared with the nitride semiconductor light-emitting element in Comparative Example 1. This seems to be attributable to the fact that unevenness was formed on both of the surface of the nitride semiconductor layer of the first conductivity type and the surface of the nitride semiconductor layer of the second conductivity type, and hence total reflection of light generated at the active layer was suppressed.

According to the present invention, it is possible to provide a method of manufacturing a nitride semiconductor light-emitting element, and the nitride semiconductor light-emitting element, both of which can suppress degradation of an active layer and improve light extraction efficiency.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A method of manufacturing a nitride semiconductor light-emitting element in which a nitride semiconductor layer of a first conductivity type, an active layer, and a nitride semiconductor layer of a second conductivity type are stacked in this order, comprising the steps of: forming unevenness at a surface of the nitride semiconductor layer of the first conductivity type; forming unevenness at a surface of the nitride semiconductor layer of the second conductivity type; and forming a first electrode on a side of the nitride semiconductor layer of the first conductivity type and a second electrode on a side of the nitride semiconductor layer of the second conductivity type such that the first and second electrodes are positioned to face each other with the active layer interposed therebetween.

2. The method of manufacturing the nitride semiconductor light-emitting element according to claim 1, wherein a conductive layer is provided at least one of between said nitride semiconductor layer of the first conductivity type and said first electrode, and between said nitride semiconductor layer of the second conductivity type and said second electrode.

3. The method of manufacturing the nitride semiconductor light-emitting element according to claim 2, wherein said conductive layer contains a conductive substance containing at least one selected from the group consisting of a nitride semiconductor, silicon carbide, silicon, zinc oxide, gallium arsenide, and gallium phosphide

4. The method of manufacturing the nitride semiconductor light-emitting element according to claim 2, wherein unevenness is formed at a surface of said conductive layer.

5. The method of manufacturing the nitride semiconductor light-emitting element according to claim 4, wherein the unevenness at the surface of said nitride semiconductor layer of the first conductivity type or the unevenness at the surface of said nitride semiconductor layer of the second conductivity type engage with the unevenness at the surface of said conductive layer.

6. The method of manufacturing the nitride semiconductor light-emitting element according to claim 1, wherein, after said nitride semiconductor layer of the first conductivity type, said active layer, and said nitride semiconductor layer of the second conductivity type are stacked in this order on a surface of a substrate, the surface having unevenness, said substrate is removed.

7. The method of manufacturing the nitride semiconductor light-emitting element according to claim 6, wherein the unevenness at the surface of said substrate is formed by stacking on the surface of said substrate a mask layer made of at least one of a silicon oxide layer and a silicon nitride layer and subsequently removing a portion of said mask layer, exposing the surface of said substrate through the removed portion of said mask layer, and subsequently removing an exposed portion of the surface of said substrate.

8. The method of manufacturing the nitride semiconductor light-emitting element according to claim 6, wherein said nitride semiconductor layer of the first conductivity type, said active layer, and said nitride semiconductor layer of the second conductivity type are stacked after a buffer layer is formed on the surface of said substrate, the surface having the unevenness.

9. The method of manufacturing the nitride semiconductor light-emitting element according to claim 8, wherein a temperature at which said buffer layer is formed is equal to or higher than a temperature at which said nitride semiconductor layer of the first conductivity type is stacked.

10. The method of manufacturing the nitride semiconductor light-emitting element according to claim 1, wherein said first conductivity type is an n type, while said second conductivity type is a p type.

11. A nitride semiconductor light-emitting element in which a nitride semiconductor layer of a first conductivity type, an active layer, and a nitride semiconductor layer of a second conductivity type are stacked in this order, wherein a first electrode on a side of said nitride semiconductor layer of the first conductivity type and a second electrode on a side of said nitride semiconductor layer of the second conductivity type are formed such that the first and second electrodes are positioned to face each other with said active layer interposed therebetween, and unevenness is formed at both of a surface of said nitride semiconductor layer of the first conductivity type and a surface of said nitride semiconductor layer of the second conductivity type.
